(19) United States
(12) Patent Application Publication
(10) Pub. No.: US 2026/0282968 A1
(43) Pub. Date: Sep. 17, 2026

(54) SEMICONDUCTOR DEVICE, SEMICONDUCTOR SYSTEM, AND MANUFACTURING METHOD FOR SEMICONDUCTOR DEVICE

(71) Applicant: Kioxia Corporation, Tokyo (JP)

(72) Inventor: Yuya MAEKAWA, Yokohama Kanagawa (JP)

(73) Assignee: Kioxia Corporation, Tokyo (JP)

(21) Appl. No.: 19/317,282

(22) Filed: Sep. 3, 2025

(30) Foreign Application Priority Data
Mar. 17, 2025 (JP) 2025-042714
May 27, 2025 (JP) 2025-087609

(51) Int. Cl. H01L 23/498; H01L 21/48; H01L 25/04

(52) U.S. Cl. CPC H10W 70/65; H10W 70/05; H10W 90/701; H10W 90/00; H10W 90/24; H10W 90/754

(57) ABSTRACT

According to one embodiment, a semiconductor device includes a circuit board, a semiconductor chip, a plurality of solder balls, and a protruding part. The circuit board includes a first surface and a second surface opposite to the first surface. The second surface includes a first region and a second region. The second region is provided at a central part of the second surface within the first region. The semiconductor chip is mounted on the first surface. The solder balls are provided in the first region on the second surface. The protruding part has insulation properties and is provided in the second region on the second surface. The protruding part protrudes in a direction from the first surface toward the second surface. The protruding part has a height lower than the solder balls. The protruding part includes first inclined surfaces decreasing in height toward the first region.

### CROSS-REFERENCE TO RELATED APPLICATIONS

This application is based upon and claims the benefit of priority from Japanese Patent Application No. 2025-042714, filed on Mar. 17, 2025, and Japanese Patent Application No. 2025-087609, filed on May 27, 2025, the entire contents of which are incorporated herein by reference.

### FIELD

Embodiments described herein relate generally to a semiconductor device, a semiconductor system, and a manufacturing method for a semiconductor device.

### BACKGROUND

There is a semiconductor system in which a semiconductor device including a semiconductor chip mounted on a circuit board is provided on a mounting substrate via solder balls.

### BRIEF DESCRIPTION OF THE DRAWINGS

FIGS. 1A to 1B are schematic cross-sectional views illustrating a configuration example of a semiconductor system according to an embodiment;

FIGS. 2A and 2B are diagrams illustrating a configuration example of the circuit board according to the embodiment;

FIGS. 3A and 3B are diagrams sequentially illustrating part of the procedure of the manufacturing method for a semiconductor system according to the embodiment;

FIGS. 4A, 4B, and 4C are diagrams sequentially illustrating part of the procedure of the manufacturing method for a semiconductor system according to the embodiment;

FIGS. 5A, 5B, and 5C are diagrams sequentially illustrating part of the procedure of the manufacturing method for a semiconductor system according to the embodiment;

FIGS. 6A and 6B are diagrams illustrating a configuration example of the circuit board according to a first modification of the embodiment; and

FIG. 7 is a diagram illustrating a configuration example of a circuit board according to a second modification of the embodiment.

### DETAILED DESCRIPTION

According to one embodiment, a semiconductor device includes a circuit board, a semiconductor chip, a plurality of solder balls, and a protruding part. The circuit board includes a first surface and a second surface opposite to the first surface. The second surface includes a first region and a second region. The second region is provided at a central part of the second surface within the first region. The semiconductor chip is mounted on the first surface of the circuit board. The solder balls are provided in the first region on the second surface of the circuit board. The protruding part has insulation properties. The protruding part is provided in the second region on the second surface of the circuit board. The protruding part protrudes in a direction from the first surface toward the second surface. The protruding part has a height lower than the solder balls. The protruding part includes first inclined surfaces decreasing in height toward the first region.

Exemplary embodiments of a semiconductor device, a semiconductor system, and a manufacturing method for a semiconductor device will be described later in detail with reference to the accompanying drawings. The present disclosure is not limited to the following embodiments.

### Configuration Example of Semiconductor Package and Semiconductor System

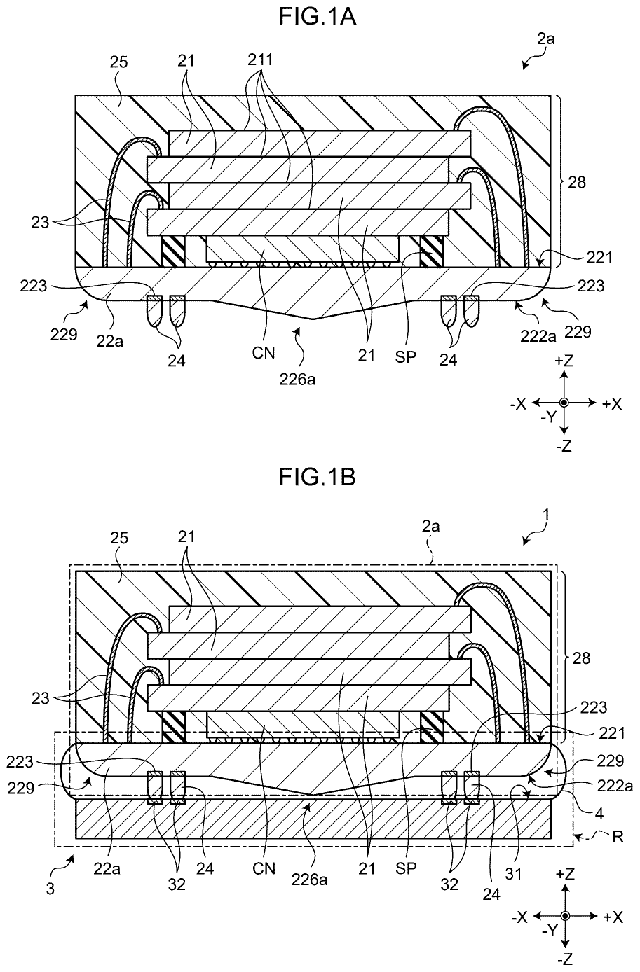

FIGS. 1A and 1B are schematic cross-sectional views illustrating a configuration example of a semiconductor system 1 according to an embodiment. More specifically, FIG. 1A is a cross-sectional view of a semiconductor package 2a, and FIG. 1B is a cross-sectional view of the semiconductor system 1 in which the semiconductor package 2a is mounted on a mounting substrate 3. The semiconductor package 2a is an example of the semiconductor device.

In the present specification, the semiconductor package 2a side of the semiconductor system 1 is referred to as an upper side, and the mounting substrate 3 side of the semiconductor system 1 is referred to as a lower side, and the upper and lower direction of the semiconductor system 1 is referred to as a Z direction. Directions orthogonal to the Z direction are defined as an X direction and a Y direction. The X direction and the Y direction are directions along a surface of a semiconductor chip 21 (described later) mounted on the semiconductor package 2a. The X direction and the Y direction are orthogonal to each other. The X direction and the Y direction are also directions along an upper surface 221 of a circuit board 22a to be described later on which the semiconductor chips 21 is stacked. In addition, a direction pointed by each of the arrows is defined as a positive direction, and the opposite direction is defined as a negative direction.

As illustrated in FIG. 1A, the semiconductor package 2a includes semiconductor chips 21, the circuit board 22a on which the semiconductor chips 21 are mounted, wires 23 that connect the circuit board 22a and the semiconductor chips 21, solder balls 24 provided on a lower surface of the circuit board 22a, and a molding material 25 that seals the semiconductor chips 21.

The circuit board 22a is configured as a multilayer substrate in which insulating layers and conductive layers described later in detail are alternately stacked. The circuit board 22a has the upper surface 221 formed in a planar shape and a lower surface 222a including a protruding part 226a and inclined surfaces 229 described later. As described in detail below, the semiconductor chips 21 sealed with the molding material 25 are mounted on the upper surface 221 of the circuit board 22a. Hereinafter, a component including the semiconductor chips 21 sealed with the molding material 25 is also referred to as a sealed part 28.

The protruding part 226a protrudes from the lower surface 222a at the central part of the lower surface 222a of the circuit board 22a. In other words, the protruding part 226a extends from the lower surface 222a of the circuit board 22a in a direction that increases the thickness of the circuit board 22a. In still other words, the protruding part 226a extends from the lower surface 222a of the circuit board 22a in a direction away from the sealed part 28 provided on the circuit board 22a. The inclined surfaces 229 are provided in an outer edge part ER to be described later of the lower surface 222a of the circuit board 22a.

The lower surface 222a is part other than the protruding part 226a and the inclined surfaces 229. The lower surface 222a is formed in a planar shape extending in parallel with the upper surface 221, for example. The upper surface 221 is an example of the first surface, and the lower surface 222a is an example of the second surface.

The semiconductor chips 21 are mounted on the upper surface 221 of the circuit board 22a. Electrode pads 223 are each formed in a partial region of the lower surface 222a of the circuit board 22a. Each of the electrode pads 223 includes, for example, copper (Cu). The solder balls 24 are each connected to a corresponding one of the electrode pads 223.

Each of the semiconductor chips 21 is a small piece obtained by dicing a silicon (Si) substrate or the like, and has a semiconductor element (not illustrated) on the main surface 211 side, for example. The semiconductor element is, for example, a nonvolatile memory such as a NAND flash memory. The semiconductor chips 21 are stacked while being shifted from each other in the X direction. As a result, a part of the main surface 211 of each semiconductor chip 21 at one end does not overlap the semiconductor chip 21 immediately above it. An electrode pad (not illustrated) is provided on the part and one end part of the main surface 211 of the uppermost semiconductor chip 21. The wires 23 are connected to the electrode pads.

The semiconductor chips 21 are supported by a spacer SP provided on the upper surface 221 of the circuit board 22a. The spacer SP is a small piece of a Si substrate or the like. The spacer SP supports the semiconductor chips 21 on the upper surface thereof. Thus, a space is formed between the upper surface 221 of the circuit board 22a and the lower surface of the lowermost semiconductor chip 21. In this space, a controller CN is provided. The controller CN includes an integrated circuit capable of controlling the operation of the semiconductor chips 21. Note that also the controller CN is a small piece obtained by dicing a Si substrate or the like, and may include an integrated circuit (not illustrated) on the upper surface.

In the Si substrate on which the integrated circuit of the controller CN is mounted, a through-hole via (not illustrated) or the like having one end part connected to the integrated circuit and penetrating the Si substrate is formed and the other end part of the through-hole via is electrically connected to the circuit board 22a via, for example, a ball grid or the like. Thus, the controller CN and the semiconductor chips 21 are electrically connected via, for example, the circuit board 22a.

The wires 23 contain, for example, at least one metal material of Au, Cu, Pd, Cu, and Ag. One ends of the wires 23 are connected to the semiconductor chips 21, and the other ends are connected to the circuit board 22a. As a result, the semiconductor chips 21 and the circuit board 22a are electrically connected.

The molding material 25 is a resin material that seals the semiconductor chips 21 mounted on the upper surface 221 of the circuit board 22a, the controller CN, the wires 23, and the like. As described above, the molding material 25 or the part sealed by the molding material 25 may be referred to as the sealed part 28.

The solder balls 24 are connected to the lower surface of the electrode pads 223 provided on the lower surface 222a of the circuit board 22a. The solder balls 24 include Sn or the like. As described later, the solder balls 24 connected to the electrode pads 223 of the circuit board 22a at the upper end are connected to the mounting substrate 3 at the lower end, whereby the semiconductor system 1 is configured.

As illustrated in FIG. 1B, the semiconductor system 1 is a storage device such as a universal flash storage (UFS) configured by mounting the semiconductor chips 21 and the semiconductor package 2a including the controller CN and the like on the mounting substrate 3. Note that, in FIG. 1B, hatching of some components such as an underfill material 4 is omitted in consideration of visibility.

The mounting substrate 3 is a printed circuit board (PCB) or the like in which insulating layers and conductive layers (not illustrated) are alternately stacked multiple times. The mounting substrate 3 includes electrode pads 32 on an upper surface 31 facing the lower surface 222a of the circuit board 22a. The electrode pads 32 are connected to the lower ends of the solder balls 24. As a result, the circuit board 22a and the mounting substrate 3 are electrically connected. The upper surface 31 is an example of the third surface.

The underfill material 4 is provided between the lower surface 222a of the circuit board 22a and the upper surface 31 of the mounting substrate 3. The underfill material 4 contains a thermosetting epoxy resin or the like. The underfill material 4 protects the bonding surfaces between the lower surface 222a of the circuit board 22a and the solder balls 24 and the bonding surfaces between the solder balls 24 and the upper surface 31 of the mounting substrate 3 from external impact, vibration, or the like.

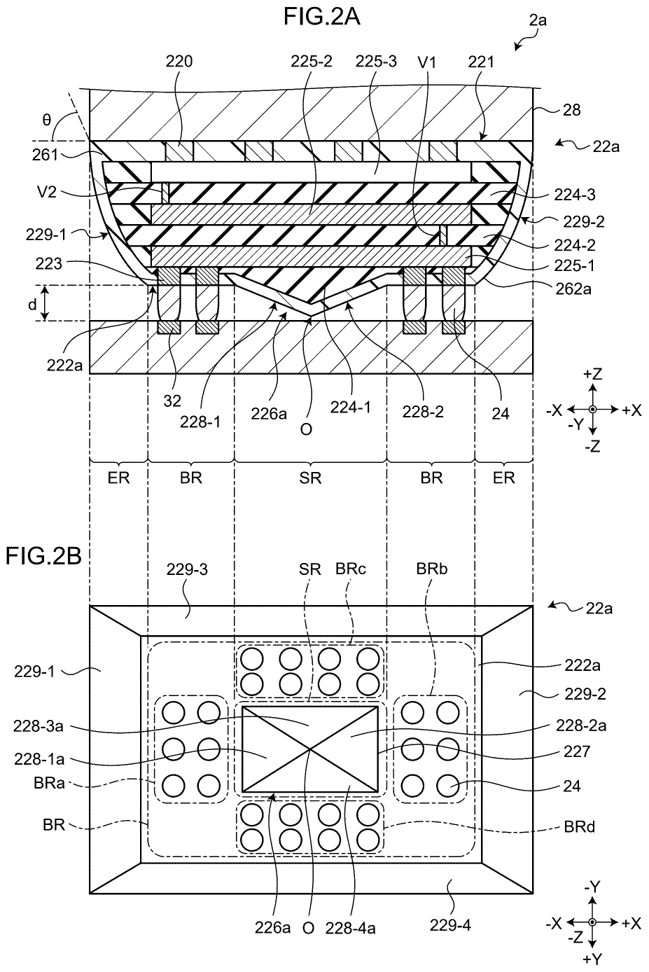

FIGS. 2A and 2B are diagrams illustrating a configuration example of the circuit board 22a according to the embodiment. More specifically, FIG. 2A is a view illustrating an enlarged cross-sectional view of the circuit board 22a including the solder balls 24 along the XZ directions. The diagram of FIG. 2A corresponds to the part in the frame line R of FIG. 1B. FIG. 2B illustrates a top view of the lower surface 222a of the circuit board 22a as viewed from the negative side of Z. The diagram of FIG. 2A represents a state of the semiconductor package 2a after being mounted on the mounting substrate 3. The diagram of FIG. 2B represents a state of only the semiconductor package 2a before being mounted on the mounting substrate 3. In FIG. 2A, illustration of some components such as the sealed part 28 formed on the upper surface 221 of the circuit board 22a and the underfill material 4 formed on the lower surface 222a of the circuit board 22a is omitted.

As illustrated in FIG. 2A, the circuit board 22a is configured as a multilayer substrate in which insulating layers 224 (224-1, 224-2, and 224-3) and conductive layers 225 (225-1, 225-2, and 225-3) are alternately stacked. The insulating layers 224-1 to 224-3 are stacked in this order from the negative side to the positive side of Z, and the conductive layers 225-1 to 225-3 are stacked in this order from the negative side to the positive side of Z.

In FIG. 2A, three insulating layers 224 and three conductive layers 225 are illustrated, but the numbers of stacked layers of the insulating layers 224 and the conductive layers 225 are not limited thereto, and can be optionally designed.

Electrode pads 220 provided on the upper surface 221 of the circuit board 22a and the electrode pads 223 provided on the lower surface 222a are electrically connected to these conductive layers 225-1 to 225-3.

The conductive layers 225-1 to 225-3 contain metal such as Cu, for example. The conductive layers 225-1 to 225-3 have wiring patterns extending in the XY directions. Via layers V1 and V2 that connect the wiring patterns of the conductive layers 225-1 to 225-3 in the Z direction are provided between the conductive layers 225-1 to 225-3. The insulating layers 224-1 to 224-3 are prepregs formed by impregnating carbon fibers, glass fibers, aramid fibers, or the like with a thermosetting resin such as an epoxy resin before curing.

The upper surface 221 of the circuit board 22a is covered by a solder resist layer 261. At least a part of the electrode pads 220 formed on the upper surface 221 of the circuit board 22a is exposed from the solder resist layer 261. These electrode pads 220 exposed from the solder resist layer 261 are connected to the wires 23 (see FIGS. 1A and 1B) of the sealed part 28.

The lower surface 222a of the circuit board 22a is covered by a solder resist layer 262a. At least respective parts of the electrode pads 223 on the lower surface 222a of the circuit board 22a are exposed from the solder resist layer 262a. These electrode pads 223 exposed from the solder resist layer 262a are connected to the respective upper ends of the solder balls 24. The solder resist layer 262a also covers the side surface of the circuit board 22a.

As illustrated in FIG. 2B, the circuit board 22a is formed in, for example, a rectangular shape when viewed from the negative side of Z. The lower surface 222a of the circuit board 22a is provided with a solder region BR in which the solder balls 24 are formed, and a protruding region SR within the solder region BR. The solder region BR is an example of the first region, and the protruding region SR is an example of the second region.

The solder region BR is a frame-shaped region surrounding the protruding region SR. The solder region BR has a region BRa and a region BRb arranged in the X direction with the protruding region SR interposed therebetween, and a region BRc and a region BRd arranged in the Y direction with the protruding region SR interposed therebetween. The region BRa is arranged on the negative side of X as viewed from the protruding region SR, the region BRb is arranged on the positive side of X as viewed from the protruding region SR, the region BRc is arranged on the negative side of Y as viewed from the protruding region SR, and the region BRd is arranged on the positive side of Y as viewed from the protruding region SR. The solder balls 24 are distributed in each of the regions BRa to BRd.

The protruding region SR is a region surrounded by the solder region BR. The protruding region SR is provided in a central part of lower surface 222a of circuit board 22a. In the protruding region SR, the protruding part 226a protruding from the lower surface 222a of the circuit board 22a in the negative direction of Z is formed.

The protruding part 226a is provided in the lowermost layer of the circuit board 22a and is part of the insulating layer 224-1.

The protruding part 226a has a quadrangular pyramid shape including a rectangular bottom surface 227, an apex O provided opposite to the bottom surface 227, and four adjacent inclined surfaces 228-1a, 228-2a, 228-3a, and 228-4a.

At this time, the protruding part 226a is preferably formed to be point-symmetric about a point in the central part of the lower surface 222a when viewed from the negative side of Z. In one example, the bottom surface 227 and the four inclined surfaces 228-1a to 228-4a are each formed to be point-symmetric about the apex O. In this case, a point in the central part of the lower surface 222a is preferably a center point of the lower surface 222a viewed from the negative side of Z. It is more preferable that the apex O of the protruding part 226a match with the center point of the lower surface 222a viewed from the negative side of Z. The negative direction of Z is an example of the first direction.

The bottom surface 227 of the protruding part 226a is in contact with the lower surface 222a of the circuit board 22a. The area (or size) of the bottom surface 227 of the protruding part 226a is preferably large as long as the area does not exceed the protruding region SR. At this time, the area of the bottom surface 227 of the protruding part 226a is at least larger than the area of the connection parts between the electrode pads 223 and the solder balls 24. The area of the bottom surface 227 of the protruding part 226a is more preferably larger than the area of the lower surface of each of the electrode pads 223 formed on the lower surface 222a.

The inclined surface 228-1a is a surface descending from the apex O toward the region BRa, the inclined surface 228-2a is a surface descending from the apex O toward the region BRb, the inclined surface 228-3a is a surface descending from the apex O toward the region BRc, and the inclined surface 228-4a is a surface descending from the apex O toward the region BRd. The inclined surfaces 228-1a to 228-4a are examples of the first inclined surface.

Hereinafter, the inclined surfaces 228-1a to 228-4a may be referred to as inclined surfaces 228a when the inclined surfaces 228-1a to 228-4a are described without distinguishing therebetween.

The height d of the protruding part 226a, namely, the distance between the lower surface 222a of the circuit board 22a and the apex O of the protruding part 226a is a height that does not exceed the respective heights of the solder balls 24 and is, for example, several tens μm to 100 μm. The height d of the protruding part 226a is preferably high as long as the height d does not exceed the respective heights of the solder balls 24.

Specifically, the height d of the protruding part 226a is at least ¼ or more of the respective heights of the solder balls 24, and more preferably ½ or more of the respective heights of the solder balls 24.

By setting the height d of the protruding part 226a to be less than the respective heights of the solder balls 24, the apex O of the protruding part 226a is prevented from coming into contact with the mounting substrate 3, and the solder balls 24 and the upper surface 31 of the mounting substrate 3 can be bonded more reliably.

In the outer edge part ER of the lower surface 222a of the circuit board 22a, inclined surfaces 229-1, 229-2, 229-3, and 229-4 descending toward the upper surface 221 of the circuit board 22a are provided. Specifically, when viewed from the protruding region SR, the inclined surface 229-1 is arranged in the outer edge part ER on the negative side of X, the inclined surface 229-2 is arranged in the outer edge part ER on the positive side of X, the inclined surface 229-3 is arranged in the outer edge part ER on the negative side of Y, and the inclined surface 229-4 is arranged in the outer edge part ER on the positive side of Y.

Each of the inclined surfaces 229-1 to 229-4 extends with curvature so as to bulge outward from the circuit board 22a. An angle θ of each of the inclined surfaces 229-1 to 229-4 with respect to the upper surface 221 of the circuit board 22a is, for example, 45°. The inclined surfaces 229-1 to 229-4 are an example of the second inclined surface.

When the inclined surfaces 229-1 to 229-4 are described without distinguishing therebetween, the inclined surfaces 229-1 to 229-4 may be referred to as inclined surfaces 229.

### Manufacturing method for Semiconductor Package

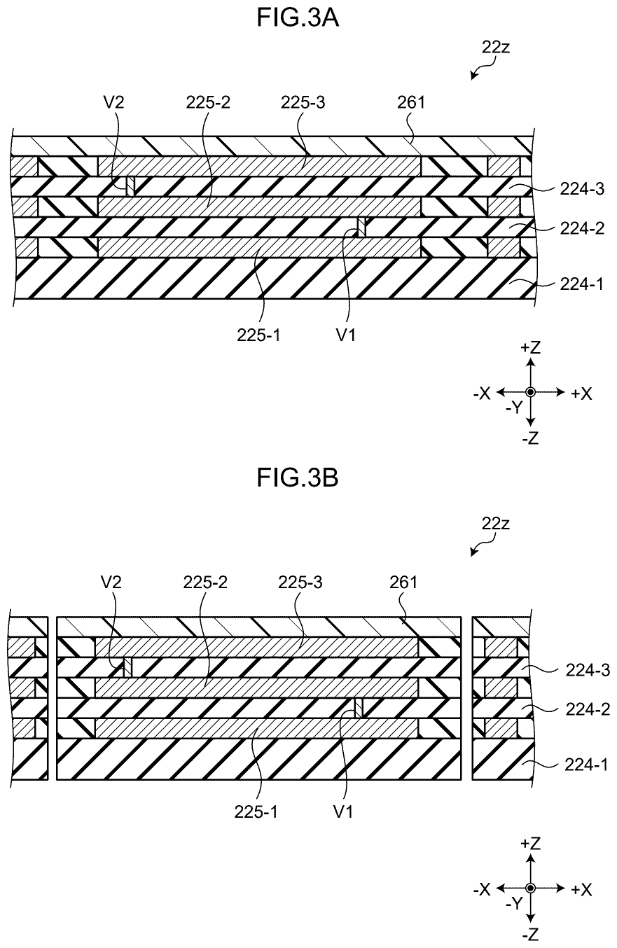

FIGS. 3A, 3B, 4A, 4B, 4C, 5A, 5B, and 5C are diagrams sequentially illustrating the procedure of the manufacturing method for the semiconductor system 1 according to the embodiment. The part of the procedure of manufacturing the semiconductor system 1 includes a process of manufacturing the circuit board 22a.

First, as illustrated in FIG. 3A, a substrate 22z in which the insulating layers 224-1 to 224-3 and the conductive layers 225-1 to 225-3 are alternately stacked in order from the bottom is formed. In the substrate 22z, a via layer V1 extending in the Z direction in the insulating layer 224-2 and connecting the conductive layer 225-1 and the conductive layer 225-2, and a via layer V2 extending in the Z direction in the insulating layer 224-3 and connecting the conductive layer 225-2 and the conductive layer 225-3 are formed.

The layer thickness of the insulating layer 224-1 on the lowermost surface of the substrate 22z is larger than the layer thicknesses of the insulating layers 224-2 and 224-3. This is because the surface of the insulating layer 224-1 is later cut to form the protruding part 226a. The solder resist layer 261 is formed on the conductive layer 225-3 on the uppermost surface of the substrate 22z.

Next, as illustrated in FIG. 3B, the substrate 22z is diced by being cut in the Z direction with a cutting blade (not illustrated).

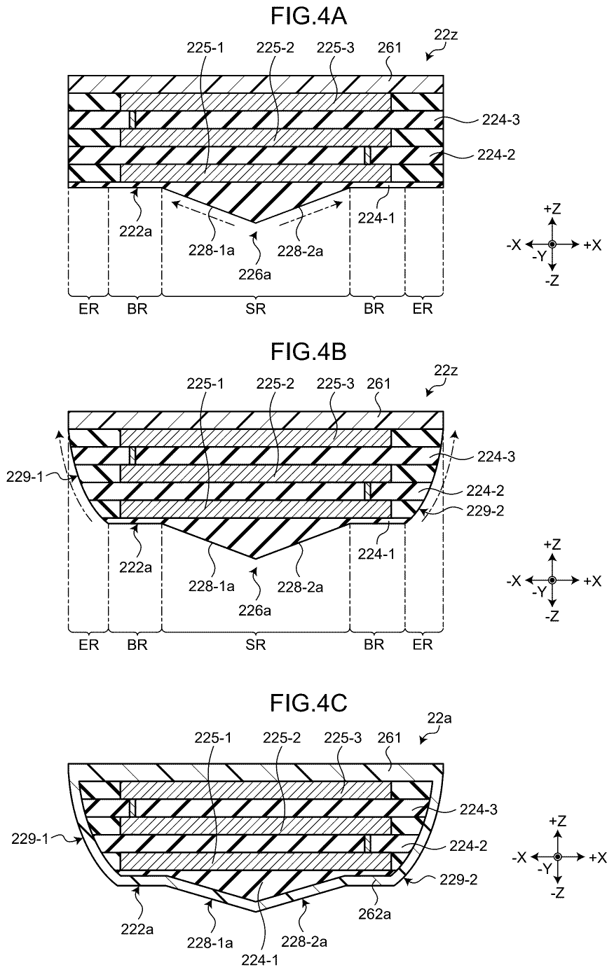

Next, as illustrated in FIG. 4A, the lower surface 222a is formed by grinding the insulating layer 224-1 of the diced substrate 22z from the negative direction of Z with a polishing pad or the like, which is used in the CMP method. At this time, the grinding is performed so as to leave the central part of the lower surface 222a of the circuit board 22a. Therefore, the central part of the lower surface 222a remains to have, for example, a quadrangular pyramid shape. As a result, the protruding part 226a protruding from the lower surface 222a is formed in the protruding region SR at the central part of the lower surface 222a. The protruding part 226a includes the inclined surfaces 228a descending toward the solder region BR.

More specifically, the pad surface of the polishing pad is pressed against the insulating layer 224-1 and rotated along the XY plane with the Z direction as a rotation axis, whereby the insulating layer 224-1 is ground. At this time, the lower surface 222a is formed by moving the pad surface in the positive direction of Z to follow the grinding removal of the insulating layer 224-1 while keeping the position on the XY plane. Further, at the central part of the unpolished lower surface of the insulating layer 224-1, the pad surface is shifted in, for example, the negative direction of X while being moved in the positive direction of Z. As a result, the inclined surface 228-1a descending toward the negative side of X is formed. Thereafter, a similar operation is performed in each of the positive direction of X and the positive and negative directions of Y from the central part of the unpolished lower surface, whereby the inclined surfaces 228-2a to 228-4a can be sequentially formed. As a result, the protruding part 226a is formed at the central part of the lower surface 222a.

Next, as illustrated in FIG. 4B, the inclined surfaces 229 descending toward the upper surface of the substrate 22z are formed in the outer edge part ER of the substrate 22z using a polishing pad or the like used in the CMP method.

Specifically, for example, the pad surface of the polishing pad is pressed against the outer edge part ER on the negative side of X, and is rotated along the XY plane with the Z direction as the rotation axis. The pad surface is shifted in, for example, the negative direction of X while being moved in the positive direction of Z. As a result, the inclined surface 229-1 descending toward the negative side of X is formed. Thereafter, a similar operation is performed in the outer edge part ER on the positive side of X and the outer edge part ER on the positive and negative sides of Y, whereby the inclined surfaces 229-2 to 229-4 can be sequentially formed. As a result, the inclined surfaces 229 descending toward the upper surface of the substrate 22z are formed in the outer edge part ER of the substrate 22z. In other words, the heights of the inclined surfaces 229 from the upper surface increase from the outer edge part ER toward the solder region BR.

Note that the order of forming the protruding part 226a and the inclined surfaces 229 is not limited to the above-described order. For example, the protruding part 226a may be formed after forming the inclined surfaces 229.

Subsequently, as illustrated in FIG. 4C, the solder resist layer 262a covering the lower surface 222a, the protruding part 226a, and the inclined surfaces 229 is formed.

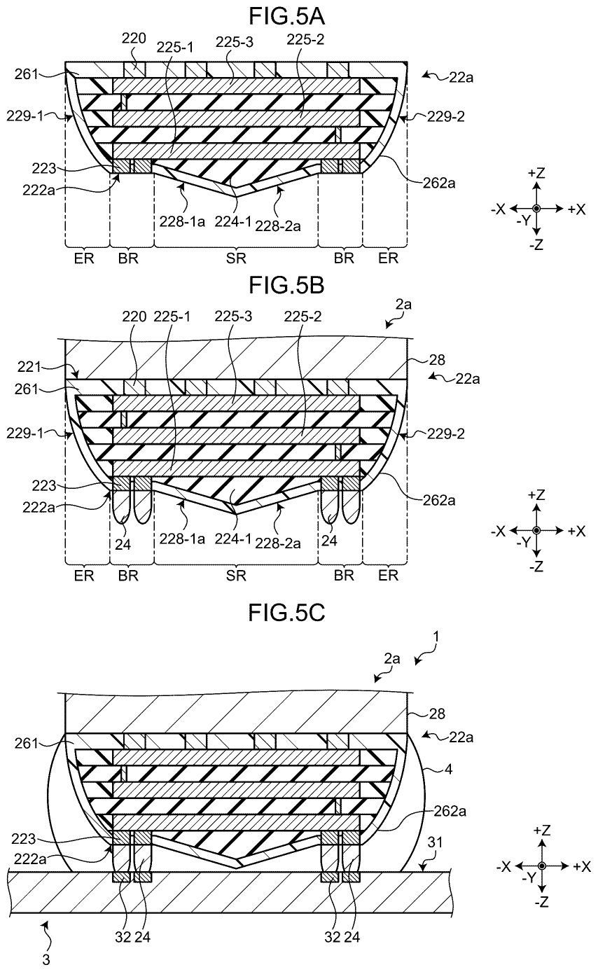

Next, as illustrated in FIG. 5A, the electrode pads 223 are formed in the solder region BR on the lower surface 222a of the circuit board 22a. Specifically, parts of the solder resist layer 262a covering the lower surface 222a of the circuit board 22a are opened to form the electrode pads 223 connected to the conductive layer 225-1.

In addition, parts of the solder resist layer 261 formed on the conductive layer 225-3 are opened to form the electrode pads 220 connected to the conductive layer 225-3.

The order of forming the electrode pads 223 and the electrode pads 220 is not limited to the above-described order. For example, after parts of the solder resist layer 261 are opened to form the electrode pads 220, parts of the solder resist layer 262a may be opened to form the electrode pads 223.

With the procedure above, the manufacturing of the circuit board 22a is completed.

Next, the semiconductor chips 21 are mounted on the circuit board 22a to form the sealed part 28. In FIGS. 5B and 5C, illustration of some components such as the sealed part 28 provided on the upper surface 221 of the circuit board 22a is omitted. In addition, hatching of some components such as the underfill material 4 is omitted in consideration of visibility.

As illustrated in FIG. 5B, the sealed part 28 is formed on the upper surface 221 of the circuit board 22a in which the electrode pads 220 has been formed. More specifically, the controller CN and the semiconductor chips 21 are sequentially stacked on the upper surface 221 of the circuit board 22a, and the controller CN and the semiconductor chips 21 are electrically connected to the electrode pads 220 by the wires 23 (see FIGS. 1A and 1B), and then these components are sealed with the molding material 25. As a result, the sealed part 28 is formed on the upper surface 221 of the circuit board 22a.

Next, the solder balls 24 connected to the lower surface of the electrode pads 223 are formed. The solder balls 24 are formed by, for example, a thermocompression bonding technique, an ultrasonic bonding technique, or a mass reflow technique, by which a plurality of solder pieces arranged in an array is dissolved to form the plurality of solder balls 24 all at once.

With the procedure above, the manufacturing of the semiconductor package 2a is completed.

Next, as illustrated in FIG. 5C, the semiconductor package 2a subjected to the above-described manufacturing process is mounted on the mounting substrate 3. Specifically, the solder balls 24 and the electrode pads 32 of the mounting substrate 3 are stacked on top and bottom of each other, and heated to 100° C. or higher in an oven or the like. As a result, the solder balls 24 and the electrode pads 32 are bonded, and the mounting substrate 3 and the semiconductor package 2a are electrically connected.

Next, a space between the lower surface 222a of the circuit board 22a and the upper surface 31 of the mounting substrate 3 is filled with the underfill material 4. When the underfill material 4 is a thermosetting resin, the underfill material 4 is heated in an oven or the like to be cured.

Then, the manufacturing of the semiconductor system 1 is completed.

### Overview

In order to evaluate reliability and life of a semiconductor system including a semiconductor package and a mounting substrate, a thermal cycling test (TCT) may be performed on the semiconductor system. In the TCT test, the semiconductor system is repeatedly placed (for example, 1500 times) under environments of low temperature (for example, −30° C.) and high temperature (for example, +125° C.).

When the semiconductor system is placed in a high-temperature environment, the underfill material provided between the lower surface of the circuit board and the upper surface of the mounting substrate expands. The lower surface of the circuit board is pushed upward and the upper surface of the mounting substrate is pushed downward, by the expanded underfill material. As a result, the solder balls connecting the lower surface of the circuit board and the upper surface of the mounting substrate are pulled in the vertical direction.

When the semiconductor system is placed in a low-temperature environment, the underfill material provided between the lower surface of the circuit board and the upper surface of the mounting substrate is shrunk. By the shrunk underfill material, the lower surface of the circuit board is pushed down, and the upper surface of the mounting substrate is pushed up. As a result, the solder balls connecting the lower surface of the circuit board and the upper surface of the mounting substrate are compressed in the vertical direction.

Due to such a stress applied to the circuit board and the mounting substrate in the vertical direction described above, a crack may be generated in the solder balls vertically connecting the circuit board and the mounting substrate. The crack extends, for example, in the XY directions or the XYZ directions in the solder ball. When the solder ball is cracked, the reliability and life of the semiconductor system may be reduced.

The semiconductor package 2a of the embodiment includes the semiconductor chips 21, the circuit board 22a on which the semiconductor chips 21 are mounted on the upper surface 221, and the solder balls 24 provided on the lower surface 222a of the circuit board 22a. The solder balls 24 are provided in the solder region BR on the lower surface 222a of the circuit board 22a. The circuit board 22a includes the protruding part 226a in the protruding region SR deviated from the solder region BR.

Since the protruding part 226a is provided on the lower surface 222a of the circuit board, the amount of the underfill material 4 provided between the lower surface 222a of the circuit board 22a and the upper surface 221 of the mounting substrate 3 can be reduced. By reducing the amount of the underfill material 4, it is possible to reduce the volume change amount due to expansion and contraction of the underfill material 4 when the semiconductor system 1 is placed in a high-temperature or a low-temperature environment. As a result, the stress applied to the circuit board 22a and the mounting substrate 3 in the vertical direction can be reduced, so that generation of a crack in the solder balls 24 can be suppressed. As a result, the reliability and life of the semiconductor system 1 are improved.

In the semiconductor package 2a of the embodiment, the height d of the protruding part 226a is set as high as possible within a range not exceeding the height of the solder balls 24. As described above, as the height d of the protruding part 226a increases, the amount of the underfill material 4 provided between the lower surface 222a of the circuit board 22a and the upper surface 31 of the mounting substrate 3 can be reduced, and the volume change amount due to expansion and contraction of the underfill material 4 can be reduced.

In the semiconductor package 2a of the embodiment, the protruding region SR is a region surrounded by the solder region BR, and the protruding part 226a provided in the protruding region SR has the inclined surfaces 228a descending toward the solder region BR.

By thus providing the inclined surfaces 228a on the lower surface 222a of the circuit board 22a, the upward stress applied to the lower surface 222a of the circuit board 22a by the expanded underfill material 4 is received and deflected into the direction along the inclined surfaces 228a. As a result, the upward stress applied to the lower surface 222a of the circuit board 22a is deflected to the outside of the circuit board 22a, and the upward stress substantially applied to the lower surface 222a of the circuit board 22a is reduced. As a result, generation of a crack in the solder balls 24 is suppressed.

In addition, since the protruding part 226a is provided at the central part of the lower surface 222a of the circuit board 22a, the upward stress applied to the lower surface 222a of the circuit board 22a by the expanded underfill material 4 is uniformly received and deflected into the directions along the inclined surfaces 228a with the central part of the lower surface 222a as the center. As a result, the upward stress applied to the lower surface 222a of the circuit board 22a can be uniformly diverted to the periphery of the circuit board 22a. Thus, generation of a crack in the solder balls 24 can be further suppressed.

In the semiconductor package 2a of the embodiment, the inclined surfaces 229 descending toward the upper surface 221 of the circuit board 22a are provided in the outer edge part ER of the lower surface 222a of the circuit board 22a. On the lower surface 222a of the circuit board 22a, the inclined surfaces 228a descending from the protruding region SR toward the solder region BR and the inclined surfaces 229 descending from the solder region BR toward the upper surface 221 of the circuit board 22a are continuously formed with the solder region BR interposed therebetween.

Therefore, the upward stress applied to the lower surface 222a of the circuit board 22a due to the expansion of the underfill material 4 can be more effectively diverted to the outside of the circuit board 22a along the continuously extending inclined surfaces 228a and inclined surfaces 229. As a result, generation of a crack in the solder balls 24 can be further suppressed.

The inclined surfaces 229 extend with curvature bulging outward from the circuit board 22a. Therefore, the upward stress applied to the lower surface 222a of the circuit board 22a due to the expansion of the underfill material 4 can be more smoothly diverted to the outside of the circuit board 22a. As a result, generation of a crack in the solder balls 24 can be further suppressed.

In the above-described embodiment, the insulating layer 224-1 is ground to form the protruding part 226a after the substrate 22z is diced, but the method for forming the protruding part 226a is not limited thereto. For example, before dicing the substrate 22z, an insulating layer on which the protruding part 226a is formed in advance may be stacked on the insulating layer 224-1 or as part of the substrate 22z instead of the insulating layer 224-1.

### First Modification

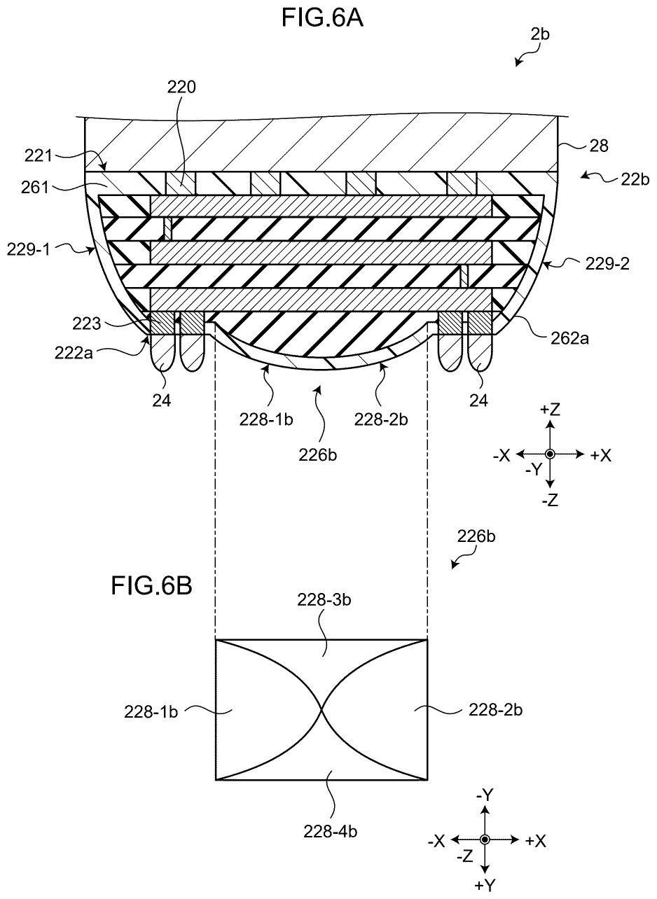

Hereinafter, a semiconductor package 2b according to a first modification of the embodiment will be described with reference to FIGS. 6A and 6B. In the semiconductor package 2b of the first modification, the shape of a protruding part 226b is different from that of the above-described embodiment. In the following description, similar reference numerals are given to similar components as those of the above-described embodiment, and the description thereof may be omitted.

FIGS. 6A and 6B are diagrams illustrating a configuration example of a circuit board 22b according to the first modification of the embodiment. More specifically, FIG. 6A is an enlarged cross-sectional view of the circuit board 22b including solder balls 24 along the XZ directions, and FIG. 6B is a top view of a protruding part 226b provided on a lower surface 222a of the circuit board 22b as viewed from the negative side of Z. FIG. 6A represents a state of only the semiconductor package 2b before being mounted on a mounting substrate 3. In FIG. 6A, illustration of some components such as a sealed part 28 formed on an upper surface 221 of the circuit board 22b is omitted.

As illustrated in FIGS. 6A and 6B, inclined surfaces 228-1b, 228-2b, 228-3b, and 228-4b of the protruding part 226b have curvature that bulges toward the negative side of Z. Since the inclined surfaces 228-1b to 228-4b bulge toward the negative side of Z, the amount of the underfill material 4 (see FIG. 1B and the like) can be further reduced. In addition, the upward stress applied to the lower surface 222a of the circuit board 22b can be more smoothly received and deflected into the direction along the inclined surfaces 228-1b to 228-4b.

Note that it is not necessary that all the inclined surfaces 228-1b to 228-4b have curvature. For example, only one or some of the inclined surfaces 228-1b to 228-4b may have curvature.

The semiconductor package 2b of the first modification of the embodiment additionally has effects similar to those of the semiconductor package 2a of the above-described embodiment.

### Second Modification

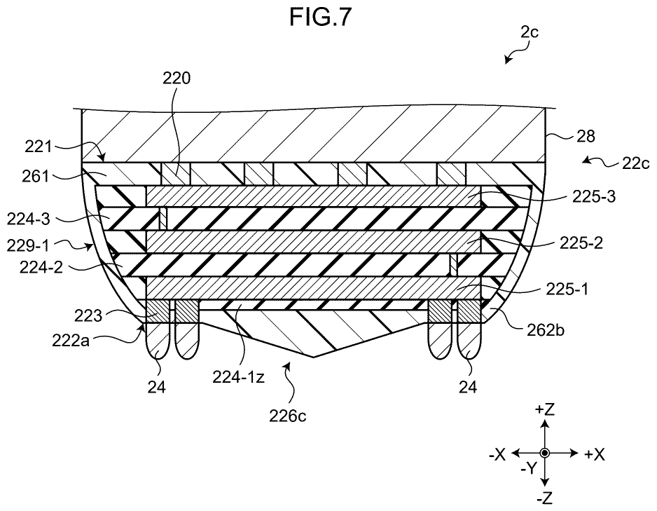

Hereinafter, a semiconductor package 2c according to a second modification of the embodiment will be described with reference to FIG. 7. In the semiconductor package 2c of the second modification, the material of a protruding part 226c is different from that of the above-described embodiment. In the following description, similar reference numerals are given to similar components as those of the above-described embodiment, and the description thereof may be omitted.

FIG. 7 is a diagram illustrating a configuration example of a circuit board 22c according to the second modification of the embodiment. More specifically, FIG. 7 illustrates an enlarged cross-sectional view of the circuit board 22c including solder balls 24 along the XZ directions. FIG. 7 represents a state of only the semiconductor package 2c before being mounted on a mounting substrate 3. In FIG. 7, illustration of some components such as the sealed part 28 formed on the upper surface 221 of the circuit board 22c is omitted.

As illustrated in FIG. 7, the protruding part 226c is formed by a solder resist layer 262b covering a lower surface 222a of the circuit board 22c.

When the protruding part 226c is formed, a substrate in which insulating layers 224-1z, 224-2, and 224-3 and conductive layers 225-1, 225-2, and 225-3 are alternately stacked is formed. Then, the substrate is diced, and inclined surfaces 229 are formed in the outer edge part ER of the diced substrate. The insulating layer 224-1z as the lowermost layer of the substrate may be formed to have the same thickness as the other insulating layers 224-2 and 224-3, and the like.

Next, the solder resist layer 262b covering the lower surface of the substrate and the inclined surfaces 229 is formed. Then, the protruding part 226c is formed by grinding part of the solder resist layer 262b provided on the lower surface of the substrate from the negative direction of Z by a CMP method or the like.

Note that the method for forming the protruding part 226c is not limited to the above-described example. For example, part of the solder resist layer 262b formed as a thick film by using an ultraviolet curable solder resist material or the like may be cured by ultraviolet rays to form a shape including the protruding part 226c.

The semiconductor package 2c of the second modification of the embodiment has effects similar to those of the semiconductor package 2a of the above-described embodiment.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a circuit board including a first surface and a second surface opposite to the first surface, the second surface including a first region and a second region, the second region being provided at a central part of the second surface within the first region;
a semiconductor chip mounted on the first surface of the circuit board;
a plurality of solder balls provided in the first region on the second surface of the circuit board; and
a protruding part with insulation properties provided in the second region on the second surface of the circuit board, the protruding part protruding in a direction from the first surface toward the second surface, the protruding part having a height lower than the solder balls, the protruding part including first inclined surfaces decreasing in height toward the first region.

2. The semiconductor device according to claim 1, wherein the protruding part is point-symmetric when viewed in a first direction perpendicular to the first surface of the circuit board.

3. The semiconductor device according to claim 1, wherein the protruding part includes curvature bulging in a direction from the first surface toward the second surface of the circuit board.

4. The semiconductor device according to claim 1, wherein
the protruding part has a quadrangular pyramid shape including a rectangular bottom surface, an apex located opposite to the bottom surface, and adjacent four inclined surfaces being the first inclined surfaces, and
the bottom surface of the protruding part is in contact with the second surface of the circuit board.

5. The semiconductor device according to claim 4, wherein
each of the solder balls is provided on the circuit board via a corresponding electrode, and
an area of the rectangular bottom surface of the protruding part is larger than areas of connection parts between the electrodes and the solder balls.

6. The semiconductor device according to claim 1, wherein
the circuit board includes second inclined surfaces in an outer edge part, the second inclined surfaces increasing in height toward a side of the first region, and
the first region is located between the second region and the outer edge part when viewed in a first direction perpendicular to the first surface.

7. The semiconductor device according to claim 6, wherein the second inclined surface extends with curvature bulging outward from the circuit board.

8. The semiconductor device according to claim 1, wherein the semiconductor chip is a nonvolatile memory or a controller.

9. A semiconductor system comprising:
a semiconductor device including
a circuit board including a first surface and a second surface opposite to the first surface, the second surface including a first region and a second region, the second region being provided at a central part of the second surface within the first region,
a semiconductor chip mounted on the first surface of the circuit board,
a plurality of solder balls provided in the first region on the second surface of the circuit board, and
a protruding part with insulation properties provided in the second region on the second surface of the circuit board, the protruding part protruding in a direction from the first surface toward the second surface, the protruding part having a height lower than the solder balls, the protruding part including first inclined surfaces decreasing in height toward the first region;
a mounting substrate including a third surface facing the second surface of the circuit board and being connected to the circuit board via the solder balls provided on the second surface of the circuit board; and
an underfill material provided between the second surface of the circuit board and the third surface of the mounting substrate.

10. The semiconductor system according to claim 9, wherein the protruding part is point-symmetric when viewed in a first direction perpendicular to the first surface of the circuit board.

11. The semiconductor system according to claim 9, wherein the protruding part includes curvature bulging in a direction from the first surface toward the second surface of the circuit board.

12. The semiconductor system according to claim 9, wherein
the protruding part has a quadrangular pyramid shape including a rectangular bottom surface, an apex located opposite to the bottom surface, and adjacent four inclined surfaces being the first inclined surfaces, and
the bottom surface of the protruding part is in contact with the second surface of the circuit board.

13. The semiconductor system according to claim 12, wherein
each of the solder balls is provided on the circuit board via a corresponding electrode, and
an area of the rectangular bottom surface of the protruding part is larger than areas of connection parts between the electrodes and the solder balls.

14. The semiconductor system according to claim 9, wherein
the circuit board includes second inclined surfaces in an outer edge part, the second inclined surfaces increasing in height toward the first region, and
the first region is located between the second region and the outer edge part when viewed in a first direction perpendicular to the first surface.

15. The semiconductor system according to claim 14, wherein the second inclined surface extends with curvature bulging outward from the circuit board.

16. The semiconductor system according to claim 9, wherein the semiconductor chip is a nonvolatile memory or a controller.

17. A manufacturing method for a semiconductor device, the manufacturing method comprising:
forming a substrate including a first surface and a second surface opposite to the first surface, the second surface including a first region and a second region, the second region being provided at a central part of the second surface within the first region;
forming a protruding part on the second surface of the substrate, the protruding part decreasing in height toward the first region of the second surface;
forming electrodes on the second surface of the substrate after the forming of the protruding part; and
mounting a semiconductor chip on the first surface of the substrate and electrically connecting the electrodes and the semiconductor chip.

18. The manufacturing method according to claim 17, further comprising forming inclined surfaces in an outer edge part of the substrate, the inclined surfaces increasing in height with respect to the first surface in a direction from an outer side of the substrate toward a side of the first region,
wherein the forming of the electrodes on the second surface is executed after the forming of the inclined surface.

19. The manufacturing method according to claim 17, further comprising dicing the substrate after the forming the substrate,
wherein the forming of the protruding part is executed after the dicing of the substrate.
